(19) United States
(12) Patent Application Publication
(10) Pub. No.: US 2025/0184639 A1
(43) Pub. Date: Jun. 5, 2025

(54) IMAGE SENSOR AND IMAGE CAPTURING APPARATUS

(71) Applicant: CANON KABUSHIKI KAISHA, Tokyo (JP)

(72) Inventor: NAOYUKI NAKAGAWARA, Tokyo (JP)

(21) Appl. No.: 18/943,100

(22) Filed: Nov. 11, 2024

(30) Foreign Application Priority Data
Nov. 30, 2023 (JP) 2023-203118

(51) Int. Cl. H04N 25/78; H01L 27/146; H04N 25/704; H04N 25/771

(52) U.S. Cl. CPC H04N 25/78; H04N 25/704; H04N 25/771; H10F 39/8063

(57) ABSTRACT

An image sensor includes a pixel portion in which unit pixels are arrayed, the unit pixels each including one microlens and a plurality of photoelectric conversion elements, a readout portion configured to read out signals from the pixel portion, the readout portion being capable of performing a first readout operation of reading out mixed signals and a second readout operation of reading out unmixed signals, a sorting portion configured to store signals obtained through the first readout operation and the second readout operation into captured image signals and focus detection signals, a first output portion configured to output the captured image signals sorted by the sorting portion; and a second output portion configured to output the focus detection signals sorted by the sorting portion.

### BACKGROUND OF THE INVENTION

### FIELD OF THE INVENTION

The present invention relates to an image sensor and an image capturing apparatus.

### DESCRIPTION OF THE RELATED ART

In recent years, for example, an increase in the number of pixels, an increase in the readout speed, and an improvement in the frame rate are advancing in image capturing apparatuses. In addition, not only generation of such images as still images and moving images, but also such control as focus adjustment, is performed using signals obtained by an image sensor.

For example, Japanese Patent Laid-Open No. 2001-124984 discloses a technique that enables focus detection based on a pupil-division method using signals obtained from an image sensor. Specifically, as each pixel in the image sensor includes one microlens and two photodiodes, the respective photodiodes receive lights that have passed through different pupil regions of a photographing lens. Focus detection can be performed by comparing output signals from these two photodiodes. Furthermore, it is also possible to generate a captured image by adding the output signals from the two photodiodes.

However, in a case where each unit pixel includes a plurality of photodiodes as in Japanese Patent Laid-Open No. 2001-124984, the amount of data read out from pixels increases, and the time period required to read out signals becomes long. The amount of data transmission from the image sensor to a signal processing IC per unit time increases due to generation of data of focus detection in addition to an increase in the number of pixels, an increase in the readout speed, and an improvement in the frame rate. The increase in the amount of data transmission per unit time causes a reduction in the frame rate.

If an attempt is made to broaden the band of data transmission and improve the processing capability of the signal processing IC in response to the increase in the amount of data transmission, the chip costs of the image sensor and the signal processing IC will increase.

### SUMMARY OF THE INVENTION

The present invention has been made in view of the aforementioned problem, and provides an image capturing apparatus capable of suppressing a reduction in the frame rate while suppressing an increase in the apparatus cost, even if the amount of data read out from an image sensor has increased.

According to a first aspect of the present invention, there is provided an image sensor, comprising: a pixel portion in which unit pixels are arrayed in a matrix, the unit pixels each including one microlens and a plurality of photoelectric conversion elements; a readout portion configured to read out signals from the pixel portion, the readout portion being capable of performing a first readout operation of reading out mixed signals obtained by mixing signals of the plurality of photoelectric conversion elements of the unit pixels, and a second readout operation of reading out unmixed signals which are not a mixture of signals of the plurality of photoelectric conversion elements of the unit pixels; a sorting portion configured to store signals obtained through the first readout operation and the second readout operation into captured image signals and focus detection signals; a first output portion configured to output the captured image signals sorted by the sorting portion; and a second output portion configured to output the focus detection signals sorted by the sorting portion.

According to a second aspect of the present invention, there is provided an image capturing apparatus, comprising: an image sensor including a pixel portion in which unit pixels are arrayed in a matrix, the unit pixels each including one microlens and a plurality of photoelectric conversion elements, a readout portion configured to read out signals from the pixel portion, the readout portion being capable of performing a first readout operation of reading out mixed signals obtained by mixing signals of the plurality of photoelectric conversion elements of the unit pixels, and a second readout operation of reading out unmixed signals which are not a mixture of signals of the plurality of photoelectric conversion elements of the unit pixels, a sorting portion configured to store signals obtained through the first readout operation and the second readout operation into captured image signals and focus detection signals, a first output portion configured to output the captured image signals sorted by the sorting portion, and a second output portion configured to output the focus detection signals sorted by the sorting portion; and at least one processor or circuit configured to function as: a first processing unit configured to process the captured image signals output from the first output portion; and a second processing unit configured to process the focus detection signals output from the second output portion.

Further features of the present invention will become apparent from the following description of exemplary embodiments with reference to the attached drawings.

### BRIEF DESCRIPTION OF THE DRAWINGS

FIG. 1 is a diagram showing a configuration of an image capturing apparatus according to a first embodiment of the present invention.

FIG. 2 is a diagram schematically showing the arrangement of pixels in an image sensor.

FIG. 3 is a diagram schematically showing a relationship between light beams emitted from an exit pupil of a photographing lens and a pixel.

FIG. 4 is a diagram showing a circuit configuration of a unit pixel of the image sensor.

FIG. 5 is a diagram showing focus detection regions that are set for a pixel array in the image sensor.

FIGS. 6A and 6B are timing charts showing an operation of reading out a row of unit pixels in the image sensor.

FIGS. 7A and 7B are diagrams illustrating a relationship between a focus state and a correlation between image signals.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

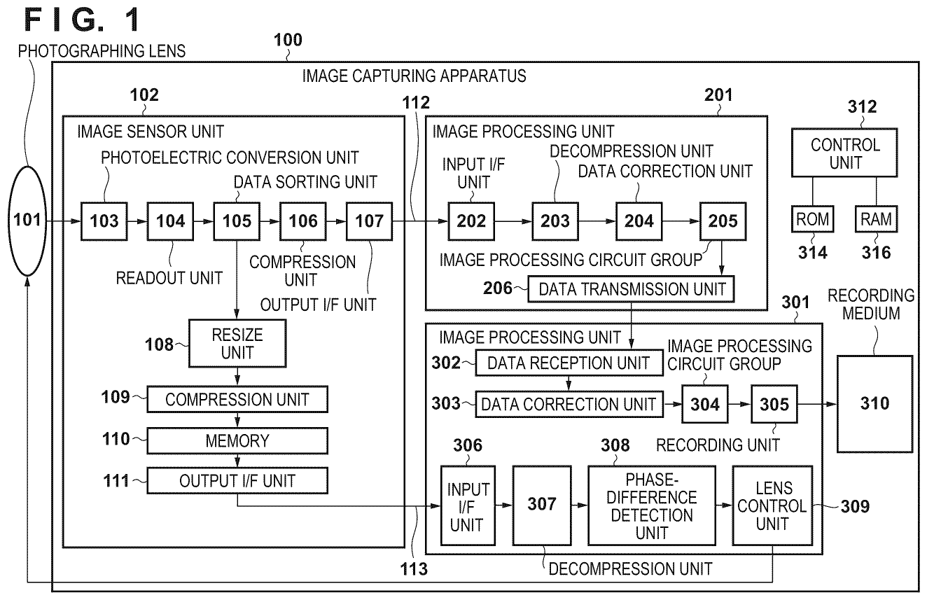

FIG. 1 is a diagram showing a configuration of an image capturing apparatus 100 according to a first embodiment of the present invention.

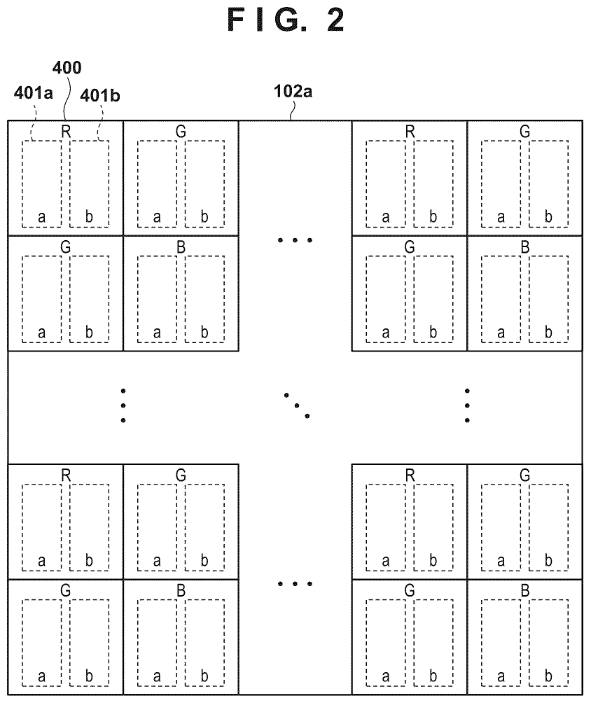

A photographing lens 101 is composed of, for example, an interchangeable lens unit attachable to and removable from the image capturing apparatus 100, guides light from a subject to an image sensor unit 102, and forms a subject image on pixels of an image sensor 102a included in the image sensor unit 102 (see FIG. 2).

The image sensor unit 102 includes the image sensor 102a that outputs image signals in accordance with incident light, such as a CMOS image sensor, a printed substrate on which the image sensor 102a is mounted, a power source for driving the image sensor 102a, and the like. More specifically, the image sensor unit 102 includes a photoelectric conversion unit 103, a readout unit 104, and a data sorting unit 105 that sorts data that has been read out into captured image data and focus detection data. It also includes a compression unit 106 that encodes the captured image data, an output interface (I/F) unit (a first output unit) 107 that transmits the captured image data, a resize unit 108 that resizes the focus detection data, and a compression unit 109 that encodes the focus detection data. It further includes a memory 110 and an output interface (I/F) unit (a second output unit) that transmits the focus detection data.

Also, the image capturing apparatus 100 includes an image processing unit 201 and an image processing unit 301 that are composed of different image processing ICs, for example. Furthermore, the image capturing apparatus 100 includes a control unit 312 that controls overall operations thereof. The control unit 312 controls an entirety of the image capturing apparatus 100 by deploying a control program stored in a ROM 314 into a RAM 316 and executing the control program.

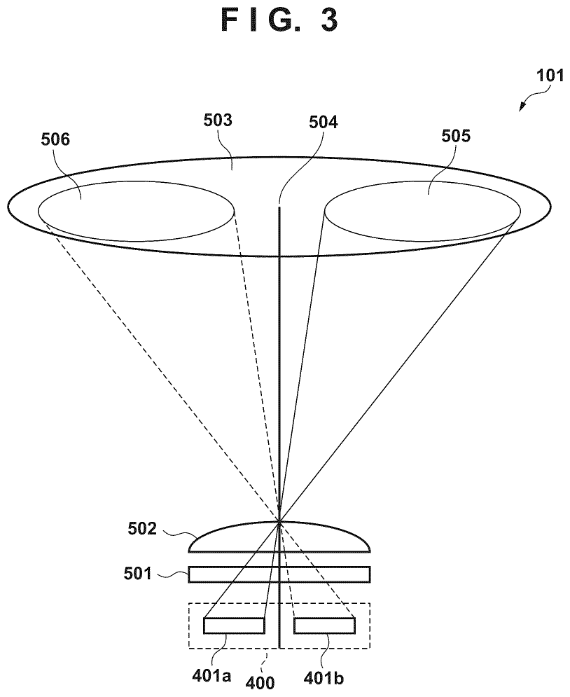

The photoelectric conversion unit 103 includes photodiodes and the like, receives incident light, and converts the incident light into electrical signals. Also, the readout unit 104 converts analog signals output from the photoelectric conversion unit 103 into digital signals. The details of these components are now described using FIG. 2 and FIG. 3.

FIG. 2 is a diagram schematically showing the arrangement of pixels in the image sensor 102a.

As shown in FIG. 2, a pixel portion of the image sensor 102a includes unit pixels 400 arrayed in a matrix, and red (R), green (G), and blue (B) color filters are arranged in a Bayer format in relation to the unit pixels 400.

Furthermore, inside each unit pixel 400, a sub-pixel a and a sub-pixel b are placed, and photodiodes 401a and 401b are placed in the sub-pixels a and b, respectively. Each of signals output from the sub-pixels a and b (unmixed signals) is used in focus detection, whereas an a-and-b mixed signal, which is a signal obtained by mixing the signals output from the sub-pixel a and the sub-pixel b, is used for image generation.

FIG. 3 is a diagram schematically showing a relationship between light beams emitted from an exit pupil of the photographing lens 101 and a unit pixel 400. In FIG. 3, components that are similar to those of FIG. 2 are shown using the same reference signs thereas.

As shown in FIG. 3, in the image sensor 102a, a color filter 501 and a microlens 502 are formed on each unit pixel 400.

Light that has passed through an exit pupil 503 of the photographing lens is made incident on a unit pixel 400 with an optical axis 504 at the center of incidence. A light beam that passes through a pupil region 505, which is a partial region of the exit pupil 503 of the photographing lens 101, passes through the microlens 502 and is received by a sub-pixel a. On the other hand, a light beam that passes through a pupil region 506, which is another partial region of the exit pupil 503, passes through the microlens 502 and is received by a sub-pixel b.

Therefore, the sub-pixel a and the sub-pixel b receive lights from different pupil regions 505 and 506 of the exit pupil 503 of the photographing lens 101, respectively. Therefore, focus detection based on a phase-difference method can be performed by comparing output signals from the sub-pixel a and the sub-pixel b. Signals of sub-pixels a are obtained from the plurality of unit pixels arranged in the row and column directions, and a subject image composed of a group of these output signals is regarded as an image signal A; signals of sub-pixels b are obtained from the plurality of unit pixels arranged in the row and column directions, and a subject image composed of a group of these output signals is regarded as an image signal B. An image displacement amount (a pupil division phase difference) is detected by executing correlation computation with respect to the image signal A and the image signal B. Furthermore, a focus position corresponding to an arbitrary subject position within a screen can be calculated by multiplying the image displacement amount by a conversion coefficient determined from a focus position of the photographing lens 101 and an optical system. Image-plane phase-detection autofocus (AF) can be performed by controlling a focus position of the photographing lens 101 based on information of the focus position calculated here. Also, a signal obtained by adding image signals A and image signals B is regarded as an image signal AB, and this image signal AB can be used for a normal shot image.

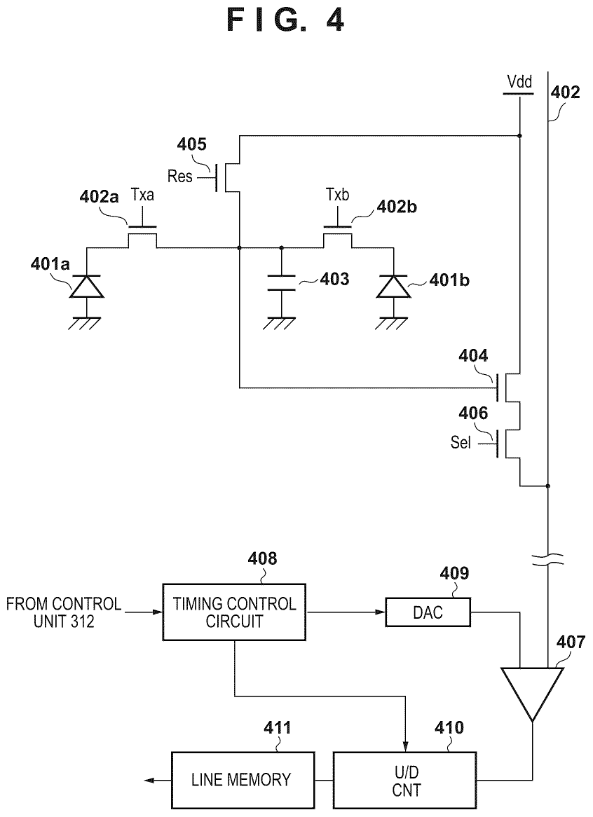

FIG. 4 is a diagram showing a circuit configuration of a unit pixel of the image sensor.

In FIG. 4, lights incident on the photodiodes (photoelectric conversion units) 401a and 401b of the above-described sub-pixels a and b are photoelectrically converted by the photodiodes 401a and 401b, and charges corresponding to the exposure amount are accumulated in the photodiodes 401a and 401b.

The charges accumulated in the photodiodes 401a and 401b are transferred to a floating diffusion (FD) unit 403 by setting each of control signals Txa and Txb, which are applied to gates of transfer gates 402a and 402b, at a high level.

The FD unit 403 is connected to a gate of a floating diffusion amplifier 404 (hereinafter referred to as an FD amplifier), and the FD amplifier 404 converts the amount of charges transferred from the photodiodes 401a and 401b into a voltage value.

A reset switch 405 is a reset switch for resetting the FD unit 403 and the photodiodes 401a and 401b; setting a control signal Res applied to a gate thereof at a high level resets the FD unit 403. Furthermore, to reset the charges in the photodiodes 401a and 401b, the control signal Res and the control signals Txa and Txb are simultaneously set at a high level. Consequently, all of the transfer gates 402a and 402b and the reset switch 405 are placed in the ON state, and the photodiodes 401a and 401b are reset via the FD unit 403.

Setting a control signal Sel applied to a gate of a pixel selection switch 406 at a high level causes pixel signals that have been converted into the voltage value by the FD amplifier 404 to be output to an AD converter (ADC) via a column output line 402.

The FD amplifier 404 operates as a source follower amplifier together with a non-illustrated constant current source connected to the column output line 402.

An ADC block includes a comparator 407, an up/down counter (U/D CNT) 410, and a DA converter (DAC) 409.

The aforementioned column output line 402 is connected to one of a pair of input terminals of the comparator 407, and the DAC 409 is connected to the other of the pair of input terminals. The DAC 409 outputs a ramp signal whose level changes like a ramp based on a reference signal input from a timing control circuit 408. Then, the comparator 407 compares the level of the ramp signal input from the DAC 409 with the level of an image signal input from the column output line 402. The timing control circuit 408 outputs the reference signal to the DAC 409 based on a command from the control unit 312 (see FIG. 1).

For example, the comparator 407 outputs a high-level comparison signal in a case where the level of the image signal is lower than the level of the ramp signal, and outputs a low-level comparison signal in a case where the level of the image signal is higher than the level of the ramp signal.

The up/down counter 410 is connected to the comparator 407, and a clock for counting time is input thereto from the timing control circuit 408. For example, the up/down counter 410 counts a clock in a time period in which the comparison signal of the comparator 407 is at a high level, or a time period in which the comparison signal is at a low level. This count processing causes output signals of the respective unit pixels 400 to be converted into digital values. The output signals converted into digital signals are stored into a line memory 411.

Next, an operation of reading out image signals A and an operation of reading out image signals AB, which are mixed signals of image signals A and image signals B, will be described. The configuration of the present embodiment allows a selection of whether to read out only the image signals AB, or to read out the image signals A and the image signals AB, on a row-by-row basis.

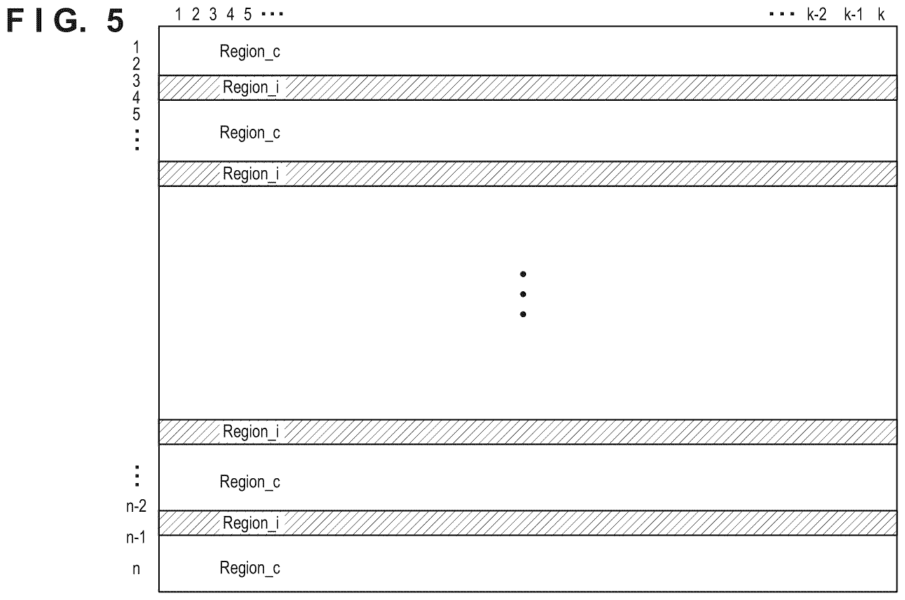

FIG. 5 shows pixel regions (Region_i) for which both of focus detection processing and image generation are performed, and pixel regions (Region_c) for which focus detection processing is not performed and only image generation is performed, in a pixel region of the aforementioned image sensor 102a.

Image signals A and image signals AB are read out from rows of unit pixels included in the regions Region_i indicated by hatched portions. Only image signals AB are read out from rows of unit pixels included in the regions Region_c, which are regions other than the regions Region_i; these image signals are not used in focus detection computation, and are used only in image generation. It is also possible to set the entire region as the pixel region (Region_i) for which both of focus detection processing and image generation are performed.

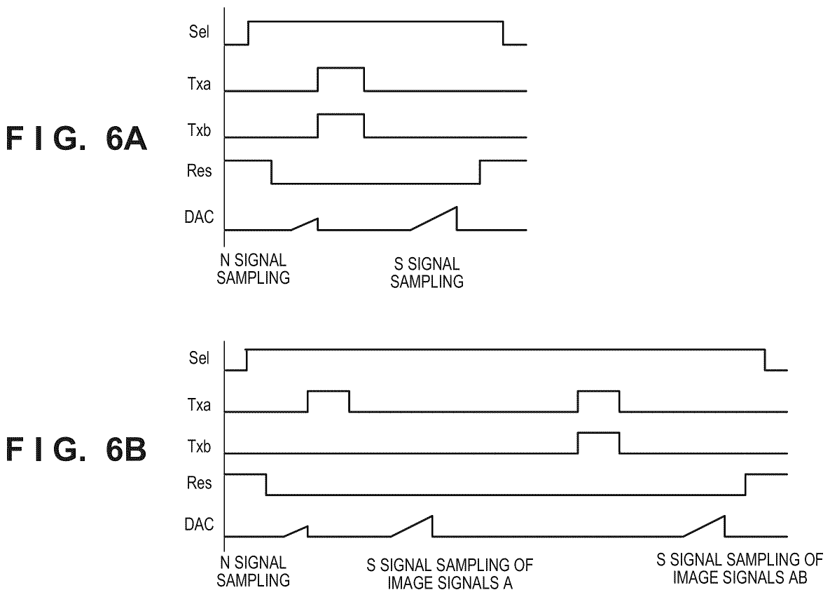

Next, an operation of reading out signals of the image sensor 102a will be described using FIGS. 6A and 6B. It is assumed that charges have already been accumulated in the photodiodes 401a and 401b.

FIG. 6A is a timing chart of a readout operation that is performed with respect to each row in the regions Region_c of FIG. 5.

The control signal Sel is set at the high level, and the pixel selection switch 406 in the unit pixels is turned ON. Thereafter, the control signal Res is set at the low level, and the reset switch 405 is turned OFF, thereby completing resetting of the FD unit 403.

Next, based on the ramp signal of the DAC 409, AD conversion is applied to a reference signal N as a reference level before turning the transfer gates 402a and 402b ON, and the reference signal N is stored into the line memory 411. An operation of reading out the reference signal N will be referred to as N-reading. Also, an input unit of the ADC includes a non-illustrated sample and hold circuit, an can hold a signal level at each of the timings of N signal sampling and S signal sampling in FIG. 6A.

Next, the control signals Txa and Txb are set at the high level, thereby turning the transfer gates 402a and 402b ON. As a result of this operation, a signal obtained by mixing charge signals accumulated in the photodiode 401a of the sub-pixel a and charge signals accumulated in the photodiode 401b of the sub-pixel b is output to the column output line 402 via the FD amplifier 404 and the pixel selection switch 406.

The signal of the column output line 402 is input to the comparator 407, and AD conversion is applied thereto based on the ramp signal of the DAC 409; the value of the difference from the reference signal N, which has been recorded earlier, is stored into the line memory 411, and AB mixed signals (image signals AB) corresponding to one row are output to the data sorting unit 105. Note that an operation of reading out charges accumulated in the photodiodes will be referred to as S-reading.

The foregoing is the operation of reading out each row of unit pixels in the regions Region_c. As a result, the image signals AB are read out.

Subsequently, an operation of reading out each row in the regions Region_i will be described using FIG. 6B. FIG. 6B is a timing chart of an operation until image signals A and image signals AB in one row of a region Region_i are read out.

The operation until the reference signal N is stored into the line memory 411 is similar to the operation illustrated in FIG. 6A.

When storing of the reference signal N has been completed, the control signal Txa is set at the high level, thereby turning the transfer gate 402a ON. This operation causes signals accumulated in the photodiode 401a of the sub-pixel a to be output to the column output line 402 via the FD amplifier 404 and the pixel selection switch 406.

The image signal A output to the column output line 402 is input to the comparator 407, and AD conversion is applied thereto based on the ramp signal of the DAC 409; the value of the difference from the reference signal N, which has been recorded earlier, is stored into the line memory 411. Then, signals of the sub-pixels a (image signals A) corresponding to one row are output to the data sorting unit 105.

Readout of the image signals A is completed with the control signal res and the control signal sel remaining at the low level and the high level, respectively. In this way, the image signal A in the FD unit 403 is held without getting reset.

The completion of readout of the image signals A is followed by an operation of reading out image signals AB. The control signals Txa and Txb are set at the high level, thereby turning the transfer gates 402a and 402b ON. This operation causes signals accumulated in the photodiode 402b of the sub-pixel b to be mixed with the signal of the sub-pixel a held in the FD unit 403, and the mixed signal is output to the column output line 402 via the FD amplifier 404 and the pixel selection switch 406. Subsequent operations are the same as the operations for the regions Region_c that have been described using FIG. 6A.

This concludes the operation of reading out each row in the regions Region_i. As a result, image signals A and image signals AB are read out sequentially. Note that an image signal B is obtained by subtracting an image signal A from an image signal AB.

The description of FIG. 1 is now resumed. The data sorting unit 105 sorts data that has been read out into captured image data and focus detection data. Specifically, the data sorting unit 105 transmits only the image signals AB that have been read out to the compression unit 106 as the captured image data. Also, the data sorting unit 105 transmits the image signals A and the image signals AB that have been read out from a pixel region for which focus detection processing is performed (Region_i) to the resize unit 108 as focus detection signals. In a case where focus detection is unnecessary, it is also possible to omit the transmission of focus detection data from the data sorting unit 105 to the resize unit 108. This allows focus detection data to be transmitted only once every multiple frames at the time of, for example, continuous shooting.

The compression unit 106 performs compression encoding with respect to the captured image data transmitted from the data sorting unit 105 using a predetermined method. The output I/F unit 107 transmits the captured image data encoded by the compression unit 106 to an input interface (I/F) unit 202 of the image processing unit 201 via a transmission path 112.

The output I/F unit 107, transmission path 112, and input I/F unit 202 require an interface (I/F) with a relatively high speed (high communication speed) because they transmit the captured image data. It is necessary to increase the transmission speed in response to an increase in the number of pixels, an increase in the readout speed, an improvement in the frame rate, and the like that are required for recent image capturing apparatuses. In order to increase the speed of signal transmission, it is sufficient to adopt a method that simply increases a frequency, and an I/F and a transmission path that support, for example, the pulse amplitude modulation (PAM) 4 transmission capable of increasing the number of bits that can be transmitted at 1 unit interval (UI). Increasing the frequency of signal transmission and supporting the PAM4 transmission cause an increase in the chip costs of the image sensor, transmission path, and signal processing unit. If an attempt is made to transmit both of the captured image data and the focus detection data using the output I/F unit 107 that supports the aforementioned high-speed transmission, the chip costs will increase; therefore, only the captured image data is transmitted using this output I/F unit 107.

The resize unit 108 resizes the focus detection data transmitted from the data sorting unit 105 using a predetermined method. It is sufficient to determine a resize method based on the data transmission speed of an output interface (I/F) unit 111, the accuracy required for focus detection, and the like. The compression unit 109 applies compression encoding to the resized focus detection data transmitted from the resize unit 108 using a predetermined method. The memory 110 can temporarily store compressed and encoded focus detection data corresponding to several frames; this makes it possible to adjust the speed for the output I/F unit 111 in a subsequent stage (adjustment of a processing speed).

The output I/F unit 111 transmits the focus detection data stored in the memory 110 to an input interface (I/F) unit 306 of the image processing unit 301 via a transmission path 113.

As the output I/F unit 111, transmission path 113, and input I/F unit 306 transmit the focus detection data that has been reduced by reading that incorporates thinning or by the resize unit, they can use an interface (I/F) with a relatively low speed (relatively low communication speed). For this reason, the output I/F unit 111, transmission path 113, and input I/F unit 306 can adopt relatively inexpensive circuits, unlike the output I/F unit 107, transmission path 112, and input I/F unit 202.

The image processing unit 201 includes an input I/F unit 202, a decompression unit 203, a data correction unit 204, an image processing circuit group 205, and a data transmission unit 206.

The image processing unit 301 is an image processing unit separate from the image processing unit 201, and includes a data reception unit 302 that receives data from the image processing unit 201, a data correction unit 303, an image processing circuit group 304, a recording unit 305, an input I/F unit 306, a decompression unit 307, a phase-difference detection unit 308, and a lens control unit 309.

For example, different image processing ICs are prepared for the image processing unit 201 and the image processing unit 301, respectively.

The input I/F unit 202 receives captured image data transmitted from the output I/F unit 107 via the transmission path 112. The input I/F unit 202 transmits the obtained captured image data to the decompression unit 203. The decompression unit 203 decodes the captured image data, which has been compressed by the compression unit 106. The decoded data is transmitted to the data correction unit 204. The data correction unit 204 executes various types of correction processing with respect to the captured image data obtained by the image sensor unit 102. For example, processing of shading correction, gain correction, defect correction, and the like is executed. The data after the correction by the data correction unit 204 is output to the image processing circuit group 205. The image processing circuit group 205 applies white balance adjustment, noise removal processing, and the like to the output data from the data correction unit 204, and transmits the processed captured image data to the data transmission unit 206. The image processing unit 201 includes a non-illustrated buffer memory and the like, and can adjust the speed of image processing (adjust the processing speed) using the buffer memory as appropriate. The data transmission unit 206 transmits the captured image data to the data reception unit 302 of the image processing unit 301.

The data reception unit 302 receives the captured image data from the data transmission unit 206, and transmits the captured image data to the data correction unit 303. The data correction unit 303 executes various types of correction processing with respect to the captured image data. For example, processing of shading correction, gain correction, defect correction, and the like is executed. The captured image data after the correction by the data correction unit 303 is output to the image processing circuit group 304. As the image processing unit 201 also includes the data correction unit 204, the correction processing may be executed in only one of the data correction unit 204 and the data correction unit 303, or the processing may be shared therebetween. The image processing circuit group 304 applies white balance adjustment, noise removal processing, and the like to the captured image data output from the data correction unit 303, and transmits the captured image data to the recording unit 305. As the image processing unit 201 also includes the image processing circuit group 205, the image processing may be executed only in one of the image processing circuit group 205 and the image processing circuit group 304, or the processing may be shared therebetween. The recording unit 305 records the captured image data into the recording medium 310. The recording medium 310 includes, for example, a memory card, such as an SD card and a CF card, stores image data, and is attachable to and removable from the image capturing apparatus 100.

The input I/F unit 306 receives focus detection data transmitted from the output I/F unit 111 via the transmission path 113. The input I/F unit 306 transmits the obtained focus detection data to the decompression unit 307. The decompression unit 307 decodes the focus detection data, which has been compressed by the compression unit 109. The decoded data is transmitted to the phase-difference detection unit 308. The phase-difference detection unit 308 calculates a focus displacement amount (defocus amount).

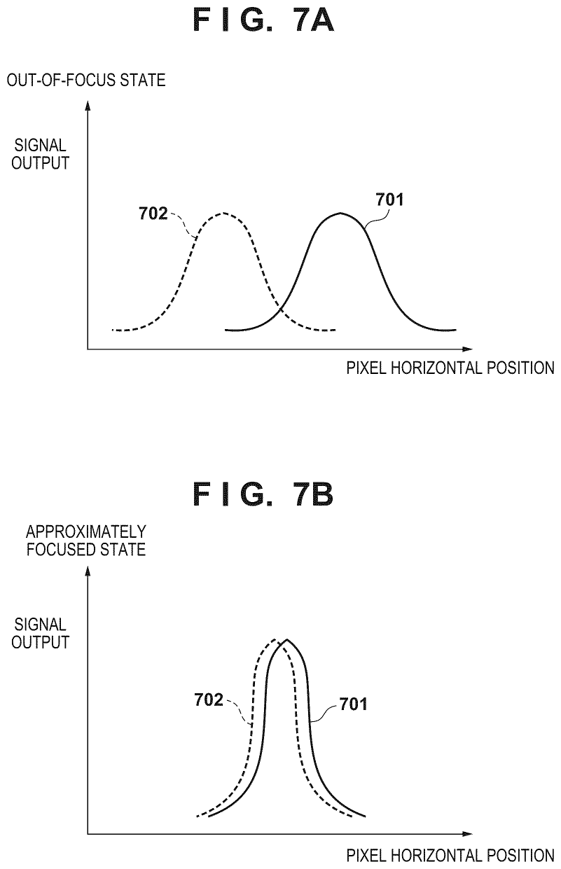

FIGS. 7A and 7B are diagrams showing a correlation between an image signal waveform 701 obtained from the sub-pixels a and an image signal waveform 702 obtained from the sub-pixels b in relation to different focus states.

As shown in FIG. 7A, in an out-of-focus state, the image signal waveforms 701 and 702, which are respectively obtained from the sub-pixels a and b, do not match and are displaced from each other significantly. When an in-focus state has been substantially achieved, the displacement between the image signal waveforms 701 and 702 decreases as shown in FIG. 7B; in the in-focus state, the image signal waveforms 701 and 702 overlap each other. In this way, the phase-difference detection unit 308 can calculate the focus displacement amount (defocus amount) from the amount of displacement between the image signal waveforms 701 and 702 obtained from the sub-pixels a and b.

The lens control unit 309 calculates driving information of the optical system based on information of the focus displacement amount (defocus amount) calculated by the phase-difference detection unit 308, and controls the photographing lens 101.

As described above, according to the first embodiment, focus detection and the like can be performed in response to an increase in the amount of data from the image sensor while suppressing an increase in the chip costs of the image sensor and signal processing ICs.

Furthermore, although it is assumed that different image processing ICs are prepared respectively for the image processing unit 201 and the image processing unit 301 in the present embodiment, it is permissible to adopt a configuration in which two chips of the image processing unit 201 and the image processing unit 301 are in one package.

### Second Embodiment

In the second embodiment, only the image signals AB that have been read out by the data sorting unit 105 are transmitted to the compression unit 106 as captured image data, and only the image signals A that have been read out from the pixel regions for which the focus detection processing is executed (Region_i) are transmitted to the resize unit 108 as focus detection signals.

The captured image data transmitted to the image processing unit 201, which is composed of the image signals AB, is decompressed by the decompression unit 203. Thereafter, this decompressed captured image data is transmitted to the image processing unit 301 via the data transmission unit 206 by passing through the data correction unit 204 and the image processing circuit group 205, and stored into a non-illustrated buffer memory. The data correction unit 303 and the image processing circuit group 304 in subsequent stages process the captured image data stored in this buffer memory, which is composed of the image signals AB, thereby generating a captured image.

Furthermore, in parallel with the foregoing, the focus detection data transmitted to the image processing unit 301, which is composed of the image signals A, is decompressed by the decompression unit 307, and image signals B are obtained by subtracting the focus detection data from the image signals AB stored in the aforementioned buffer memory. A phase difference can be detected from these image signals A and image signals B. In this way, the focus detection data can be further reduced.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD) TM), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-203118, filed Nov. 30, 2023, which is hereby incorporated by reference herein in its entirety.

What is claimed is:

1. An image sensor, comprising:
a pixel portion in which unit pixels are arrayed in a matrix, the unit pixels each including one microlens and a plurality of photoelectric conversion elements;
a readout portion configured to read out signals from the pixel portion, the readout portion being capable of performing a first readout operation of reading out mixed signals obtained by mixing signals of the plurality of photoelectric conversion elements of the unit pixels, and a second readout operation of reading out unmixed signals which are not a mixture of signals of the plurality of photoelectric conversion elements of the unit pixels;
a sorting portion configured to store signals obtained through the first readout operation and the second readout operation into captured image signals and focus detection signals;
a first output portion configured to output the captured image signals sorted by the sorting portion; and
a second output portion configured to output the focus detection signals sorted by the sorting portion.

2. The image sensor according to claim 1, wherein
with respect to the unit pixels in a first region of the pixel portion, the first readout operation is performed and the mixed signals are read out, and with respect to a second region different from the first region of the pixel portion, the first readout operation and the second readout operation are performed and the mixed signals and the unmixed signals are read out.

3. The image sensor according to claim 2, wherein
the sorting portion distributes the mixed signals that have been read out from the first region to the first output unit, and distributes the mixed signals and the unmixed signals that have been read out from the second region to the second output unit.

4. The image sensor according to claim 1, wherein
a communication speed at which signals are output from the first output portion is higher than a communication speed at which signals are output from the second output portion.

5. The image sensor according to claim 1, further comprising
a resize portion configured to reduce the focus detection signals before the focus detection signals are output from the second output portion.

6. The image sensor according to claim 1, further comprising
a memory configured to adjust a processing speed in accordance with a communication speed of the second output portion.

7. The image sensor according to claim 1, wherein
the sorting portion transmits the focus detection signals to the second output portion once every multiple frames.

8. An image capturing apparatus, comprising:
an image sensor including
a pixel portion in which unit pixels are arrayed in a matrix, the unit pixels each including one microlens and a plurality of photoelectric conversion elements,
a readout portion configured to read out signals from the pixel portion, the readout portion being capable of performing a first readout operation of reading out mixed signals obtained by mixing signals of the plurality of photoelectric conversion elements of the unit pixels, and a second readout operation of reading out unmixed signals which are not a mixture of signals of the plurality of photoelectric conversion elements of the unit pixels,
a sorting portion configured to store signals obtained through the first readout operation and the second readout operation into captured image signals and focus detection signals,
a first output portion configured to output the captured image signals sorted by the sorting portion, and
a second output portion configured to output the focus detection signals sorted by the sorting portion; and
at least one processor or circuit configured to function as:
a first processing unit configured to process the captured image signals output from the first output portion; and
a second processing unit configured to process the focus detection signals output from the second output portion.

9. The image capturing apparatus according to claim 8, wherein
the first processing unit transmits the captured image signals to the second processing unit.

10. The image capturing apparatus according to claim 9, wherein
the second processing unit records the captured image signals into a recording medium.

11. The image capturing apparatus according to claim 8, wherein
the second processing unit performs focus detection based on the focus detection signals.
